(19) United States
(12) Patent Application Publication
(10) Pub. No.: US 2015/0044532 A1
(43) Pub. Date: Feb. 12, 2015

(54) BATTERY WITH VISUAL INDICATOR OF POWER LEVEL AND ELECTRONIC DEVICE

(71) Applicant: HON HAI PRECISION INDUSTRY CO., LTD., New Taipei (TW)

(72) Inventor: JEN-JUNG HSIAO, New Taipei (TW)

(21) Appl. No.: 14/455,278

(22) Filed: Aug. 8, 2014

(30) Foreign Application Priority Data
Aug. 9, 2013 (TW) 102128749

(51) Int. Cl. H01M 10/48; G01R 31/36

(52) U.S. Cl. CPC H01M 10/488; G01R 31/3606; G01R 31/3686; H01M 10/486; H01M 2220/30
USPC 429/92; 429/90

(57) ABSTRACT

A battery indicating its own power level and temperature includes a transparent enclosure, a first, a second, and a third switch, a first, a second, and a third lighting member coupled to the first switch and a main chip. The main chip switches on the first and second switches to enable visible color indications of two different power states of the battery, and switches on the third lighting member to indicate with color a high battery temperature, all colors being visible through the transparent enclosure.

### FIELD

The present disclosure generally relates to a battery with visible indicator and an electronic device with such battery. cl BACKGROUND

An electronic device, such as, a notebook computer includes a battery, and a rear glass panel of the electronic device can be transparent. The battery can be seen through the transparent rear panel of the electronic device.

### BRIEF DESCRIPTION OF THE DRAWINGS

Many aspects of the embodiments can be better understood by reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of one embodiment of a battery.

FIG. 2 is a view of one embodiment of a self-indicating battery used in an electronic device.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be made to function without these specific details. In other instances, methods, procedures and components have not been described in detail so as not to obscure the feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure are as follows.

The term “coupled” is defined as connected, whether directly or indirectly through intervening components, and is not necessarily limited to physical connections. The connection can be such that the objects are permanently connected or releasably connected. The term “comprising,” means “including, but not necessarily limited to” and specifically indicates open-ended inclusion or membership in the so-described combination, group, series, or the like.

The present disclosure describes a battery comprising a transparent enclosure, a cell configured for supplying power to an electronic device, a main chip, a battery capacity sensor coupled to the main chip, a switch assembly comprising a first switch coupled to the cell and the main chip and a lighting assembly. The lighting assembly comprises a first lighting member, the first lighting member being coupled to the first switch. The battery capacity sensor is used to sense a first state of the cell and send a first signal to the main chip, and the main chip is configured to switch on the first switch to enable the first lighting member to emit light of a first color to pass through the transparent enclosure when the first signal is received.

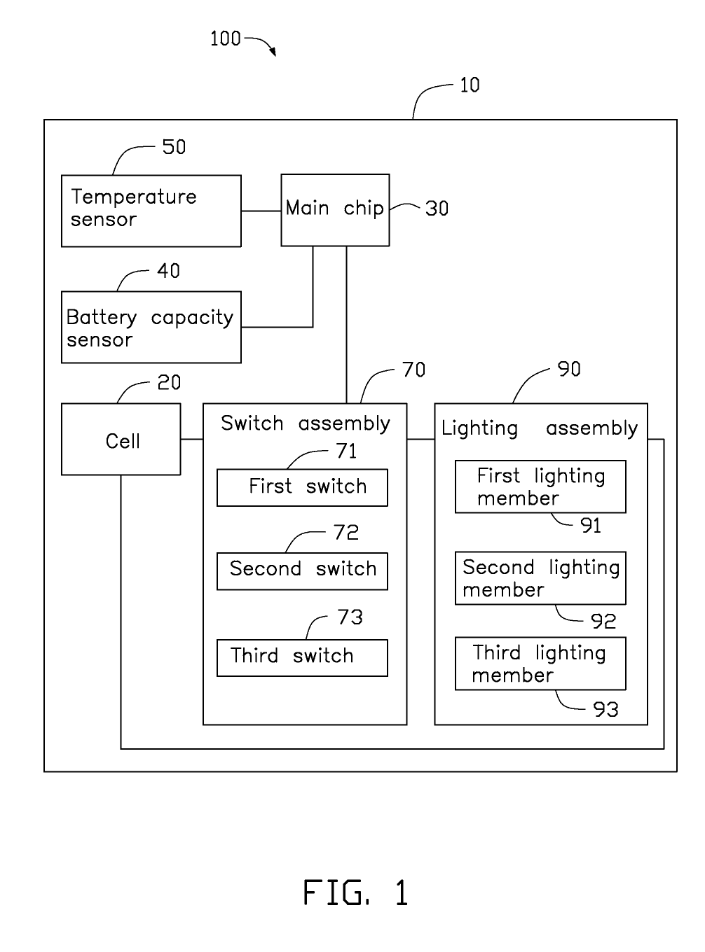

FIG. 1 shows an embodiment of a battery 100. The battery 100 includes a transparent enclosure 10, a cell 20, a main chip 30, a battery capacity sensor 40, a temperature sensor 50, a switch assembly 70, and a lighting assembly 90. The transparent enclosure 10 can be made of transparent material, for example, the transparent enclosure 10 can be made of glass. The cell 20, the main chip 30, the battery capacity sensor 40, the temperature sensor 50, the switch assembly 70, and the lighting assembly 90 can be received in the transparent enclosure 10. The battery capacity sensor 40 can sense a battery level of the cell 20, and the temperature sensor 50 can sense the temperature of the battery body 11.

The lighting member assembly 90 includes a plurality of lighting members. For clarity, a first lighting member 91, a second lighting member 92, and a third lighting member 93 are shown in FIG. 1. In one embodiment, the three lighting members are three light emitting diodes. The different lighting members emit different colors of light. The main chip 30 is coupled to the battery capacity sensor 40 and the temperature sensor 50. The main chip 30 is also coupled to the switch assembly 70. The switch assembly 70 can include a plurality of switches. Corresponding to the three lighting members, there is a first switch 71, a second switch 72, and a third switch 73 shown in FIG. 1. In at least one embodiment, the first switch 71 is coupled to the first lighting member 91, the second switch 72 is coupled to the second lighting member 92, and the third switch 73 is coupled to the third lighting member 93.

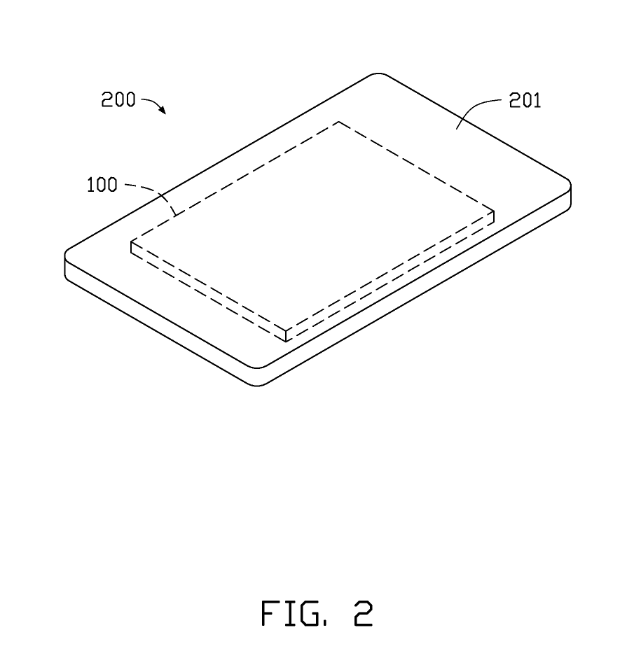

FIG. 2 shows the battery 100 used in an electronic device 200. The electronic device 200 can be a mobile telephone. The electronic device 200 can comprise a transparent rear panel 201. The cell 20 supplies power for the electronic device 200. When the battery capacity sensor 40 senses a first status of the cell 20, for example, that the current electrical quantity is less than 10% of the total possible charge, a first signal is sent to the main chip 30. The main chip 30 controls the first switch 71 to switch on to enable the cell 20 to supply power to the first lighting member 91. The first light member emits light of a first color, such as yellow light, and the first color light can be seen through the transparent enclosure 10 and the transparent rear panel 201, thereby users can see the first color light through the transparent rear panel 201. At this time, the transparent rear panel 201 can appear to be yellow in color.

When the battery capacity sensor 40 senses a second status of the cell 20, for example, that the battery is charged to the full, a second signal is sent to the main chip 30. The main chip 30 controls the second switch 72 to switch on to enable the cell 20 to supply power to the second lighting member 92. The second light member 92 emits light of a second color, such as blue light, and the second color light can be seen through the transparent enclosure 10 and the transparent rear panel 201, thereby users can see the second color light through the transparent rear panel 201. At this time, the transparent rear panel 201 can appear to be a blue color.

When the temperature sensor 50 senses that the temperature of the battery 100 is higher than a predetermined value, the temperature sensor 50 sends a danger signal to the main chip 30. The main chip 30 controls the third switch 73 to switch on to enable the cell 20 to supply power to the third lighting member 93. The third light member 93 emits light of a third color, such as red light, and the third color light can be seen through the transparent enclosure 10 and the transparent rear panel 201, thereby users can see the third color light through the transparent rear panel 201. At this time, the transparent rear panel 201 appears to be colored red.

The embodiments shown and described above are only examples. Many details are often found in the art such as the other features of a battery, therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in the matters of shape, size and arrangement of parts within the principles of the present disclosure up to and including the full extent established by the broad general meaning of the terms used in the claims. It will therefore be appreciated that the embodiments described above may be modified within the scope of the claims.

What is claimed is:

1. A battery (100), comprising:
a transparent enclosure (10);
a cell (20) configured for supplying power of an electronic device (200);
a main chip (30);
a battery capacity sensor (40) coupled to the main chip (30);
a switch assembly (70) comprising a first switch (71) coupled to the cell (20) and the main chip (30); and
a lighting assembly (90) comprising a first lighting member (91), the first lighting member (91) coupled to the first switch (71); and
wherein the battery capacity sensor (40) is configured to sense a first state of the cell (20) to send a first signal to the main chip (30), and the main chip (30) is configured to switch on the first switch (71) to enable the first lighting member (91) to emit a first color light to pass through the transparent enclosure (10) after receiving the first signal.

2. The battery (100) of claim 1, further comprising a second switch (72) and a second lighting member (92) coupled to the second switch (72), wherein the main chip (30) switches on the second switch (72) to enable the second light member (92) to emit a second color light to pass through the transparent enclosure (10) after the battery capacity sensor (40) sensing a second state of the cell (20).

3. The battery (100) of claim 2, further comprising a temperature sensor (50) connected to the main chip (30), a third switch (73) and a third lighting member (93) coupled to the third switch (73), wherein the temperature sensor (50) is configured to sensor a temperature of the battery (100), when the temperature sensor (50) sensors a temperature of the battery (100) is higher than a predetermined value, the temperature sensor (50) is configured to send a dangerous signal to the main chip (30), and the main chip (30) switches on the third switch (73) to enable the third light member (93) to emit a third color light to pass through the transparent enclosure (10).

4. The battery (100) of claim 3, wherein the first status is that a current electronic quantity is less than a scale value of a total electronic quantity; and the second status is that the battery (10) is charged to be full.

5. The battery (100) of claim 1, wherein the first status is that a current electronic quantity is less than a scale value of a total electronic quantity.

6. The battery (100) of claim 1, wherein the first status is that the cell (20) is charged to be full.

7. The battery (100) of claim 1, wherein the first lighting member (91) is alight emitting diode.

8. A battery (100), comprising:
a transparent enclosure (10);
a cell (20);
a first switch (71);
a first lighting member (91), the first lighting member (91) coupled to the first switch (71); and
a main chip (30) connected to the first switch (71), the main chip (30) switching on the first switch (71) to enable the first lighting member (91) to emit a first color light to pass through the transparent enclosure (10) after sensing a first status of the cell (20).

9. The battery (100) of claim 8, further comprising a second switch (72) and a second lighting member (92) coupled to the second switch (72), wherein the main chip (30) switches on the second switch (72) to enable the second light member (92) to emit a second color light to pass through the transparent enclosure (10) after sensing a second status of the cell (20).

10. The battery (100) of claim 9, further comprising a third switch (73) and a third lighting member (93) coupled to the third switch (73), wherein the main chip (30) switches on the third switch (73) to enable the third light member (93) to emit a third color light to pass through the transparent enclosure (10) after sensing a temperature of the battery (100).

11. The battery (100) of claim 10, wherein the first status is that a current electronic quantity is less than a scale value of a total electronic quantity; the second status is that the cell (20) is charged to be full; and the temperature of the battery (100) is greater than a reference value.

12. The battery (100) of claim 8, wherein the first status is that a current electronic quantity is less than a scale value of a total electronic quantity.

13. The battery (100) of claim 8, wherein the first status is that the cell (20) is charged to be full.

14. The battery (100) of claim 8, wherein the first status is that a temperature of the battery (100) is greater than a reference value.

15. The battery (100) of claim 14, wherein the battery (100) comprises a temperature sensor (50) received in the transparent enclosure (10) and connected to the main chip (30);
the temperature sensor (50) is configured to sense the temperature of the battery (100) and send the temperature to the main chip (30).

16. The battery (100) of claim 8, wherein the first lighting member (91) is a light emitting diode.

17. The battery (100) of claim 8, wherein the first switch (71) is coupled between the first lighting member (91) and the cell (20).

18. An electronic device (200), comprising:
a transparent rear panel (201); and
a battery (100) comprising a transparent enclosure (10); a cell (20); a first switch (71); a first lighting member (91), the first lighting member (91) coupled to the first switch (71); and a main chip (30), the main chip (30) switching on the first switch (71) to enable the first lighting member (91) to emit a first color light to pass through the transparent enclosure (10) and the transparent rear panel (201) after sensing a status of the cell (20).

19. The electronic device (200) of claim 8, wherein the battery (100) further comprises a battery capacity sensor (40), and the battery (100) is configured to sense the status of the cell (20).

20. The electronic device (200) of claim 8, wherein the battery (100) further comprises a temperature sensor (50), and the temperature sensor (50) is configured to sense a temperature of the battery (100).
